(19) United States
(12) Patent Application Publication
(10) Pub. No.: US 2022/0403503 A1
(43) Pub. Date: Dec. 22, 2022

(54) FILM FORMING APPARATUS AND FILM FORMING METHOD

(71) Applicant: TOKYO ELECTRON LIMITED, Tokyo (JP)

(72) Inventors: Hiroyuki Iwashita, Nirasaki City (JP); Toru Kitada, Nirasaki City (JP); Atsushi Shimada, Nirasaki City (JP)

(21) Appl. No.: 17/840,055

(22) Filed: Jun. 14, 2022

(30) Foreign Application Priority Data
Jun. 18, 2021 (JP) 2021-101865

(51) Int. Cl. C23C 14/34; C23C 14/00; C23C 14/10; C23C 14/54

(52) U.S. Cl. CPC C23C 14/34; C23C 14/0042; C23C 14/0073; C23C 14/10; C23C 14/542

(57) ABSTRACT

A film forming apparatus for forming a metal oxide film on a substrate, includes: a substrate support part configured to support the substrate; a heating mechanism configured to heat the substrate supported by the substrate support part; a processing container in which the substrate support part is provided; a holder configured to hold a metal material target inside the processing container and connected to a power source; a gas supply part configured to supply an oxygen gas into the processing container; and a controller, wherein the controller is configured to control the heating mechanism, the power source, and the gas supply part so as to execute alternately and repeatedly: forming a predetermined film on the substrate inside the processing container by reactive sputtering in a metal mode; and forming a target metal oxide film by causing the predetermined film to react with an oxygen gas inside the processing container.

### CROSS-REFERENCE TO RELATED APPLICATION

This application is based upon and claims the benefit of priority from Japanese Patent Application No. 2021-101865, filed on Jun. 18, 2021. the entire contents of which are incorporated herein by reference.

### TECHNICAL FIELD

The present disclosure relates to a film forming apparatus and a film forming method.

### BACKGROUND

In the related art, there is a known a method in which metallic titanium is used as a target, a mixed gas of argon and oxygen is used as a gas introduced into a sputtering device, the gas pressure of the introduced gas is made higher than 10 Torr, and a titanium oxide film of anatase-type crystals is formed. by reactive sputtering with mixed gas plasma.

### PRIOR ART DOCUMENT

[Patent Document]

Patent Document 1: Japanese Laid-Open Patent Publication No. 2000-126613

### SUMMARY

According to one embodiment of the present disclosure, there is provided a film forming apparatus for forming a metal oxide film on a substrate, including: a substrate support part configured to support the substrate; a heating mechanism configured to heat the substrate supported by the substrate support part; a processing container in which the substrate support part is provided; a holder configured to hold a metal material target inside the processing container and connected to a power source; a gas supply part configured to supply an oxygen gas into the processing container; and a controller, wherein the controller is configured to control the heating mechanism, the power source, and the gas supply part so as to execute alternately and repeatedly: forming a predetermined film on the substrate inside the processing container by reactive sputtering in a metal mode; and forming a target metal oxide film by causing the predetermined film to react with an oxygen gas inside the processing container.

### BRIEF DESCRIPTION OF DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a diagram showing the relationship between a flow rate of an oxygen gas, a deposition rate and a refractive index during reactive sputtering.

FIG. 2 is a vertical sectional view showing an outline of the configuration of a film forming apparatus 1 according to the present embodiment,

FIG. 3 is a diagram showing a state inside a processing container during a film forming process.

FIG. 4 is a diagram showing a state inside the processing container during the film forming process.

FIG. 5 is a diagram showing a refractive index of a TiO₂ film actually formed by a film forming method according to the present embodiment and a deposition rate at that time.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

In a manufacturing process of a semiconductor device or the like, a film forming process for forming a desired film such as a metal oxide film or the like is performed on a substrate such as a semiconductor wafer (hereinafter referred to as “wafer”) or the like. Reactive sputtering may be used for the film forming process. For example, when forming a titanium oxide film as a metal oxide film by reactive sputtering, the metal particles released from a target react with an oxygen gas as a reactive gas to form a titanium oxide film on the substrate.

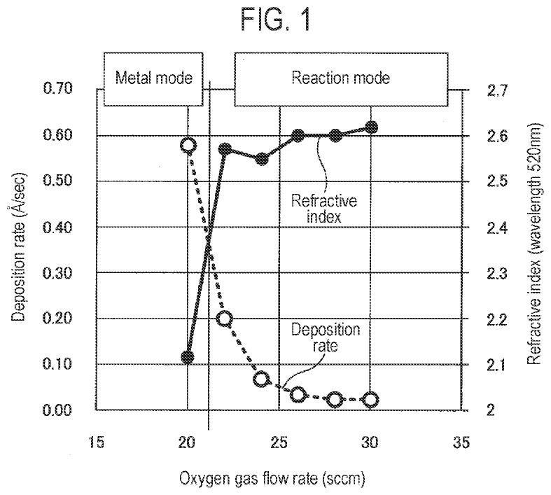

By the way, the characteristics, particularly the refractive index, of the formed titanium oxide film varies depending on the supply flow rate of the oxygen gas during the reactive sputtering. Specifically, as shown in FIG. 1, when the reactive sputtering is performed in a reaction mode (also referred to as poison mode) in which the supply flow rate of the oxygen gas is large, a titanium oxide film having a high refractive index can be obtained as compared with a case where the reactive sputtering is performed in a metal mode in which the supply flow rate of the oxygen gas is small. Although the titanium oxide film having a high refractive index can be obtained in the reaction mode as described above, the deposition rate in the reaction mode is lower than that in the metal mode. It is required to increase the deposition rate for mass production and the like. This point is the same for other metal oxide films.

Thus, the technique according to the present disclosure forms a metal oxide film having a high refractive index at a deposition rate.

Hereinafter, the film forming apparatus and the film forming method according to the present embodiment will be described with reference to the drawings, in the subject specification and the drawings, elements having substantially the same functional configuration are designated by the same reference numerals, and the duplicate description thereof will be omitted.

<Film Forming Apparatus>

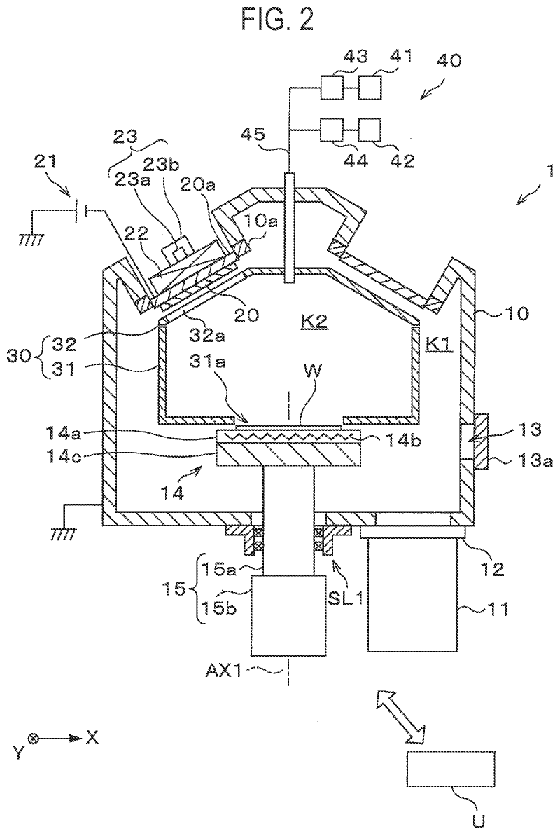

FIG. 2 is a vertical sectional view showing an outline of the configuration of the film forming apparatus 1 according to the present embodiment.

The film forming apparatus 1 of FIG. 2 forms a metal oxide film on a wafer W as a substrate. The metal oxide film formed by the film forming apparatus 1 is, for example, a titanium dioxide (TiO₂) film, a silicon dioxide (SiO₂) film, or a TiSiOₓ film. Hereinafter, the film forming apparatus 1 will be described based on an example of forming a TiO₂ film.

The film forming apparatus 1 includes a processing container 10. The processing container 10 is configured to be depressurized and to accommodate the wafer W. The processing container 10 is formed of, for example, aluminum and is connected to a ground potential. An exhaust device 11 for reducing the pressure in the space K1 inside the processing container 10 is connected to the bottom of the processing container 10. The exhaust device 11 includes a vacuum pump (not shown) and the like, and is connected to the processing container 10 via, for example, an APC valve 12.

Further, a wafer loading/unloading port 13 is formed on one side wall (the X-direction positive side wall in the figure) of the processing container 10, and a gate valve 13a for opening and closing the loading/unloading port 13 is provided at the loading/unloading port 13.

A stage 14 as a substrate support part is provided in the processing container 10. The stage 14 supports the wafer W placed on the stage 14. Specifically, the wafer W is horizontally placed on the stage 14 so as to face a processing space K2 defined by a shield part 30 described later. The stage 14 includes an electrostatic chuck 14a, a heater 14b as a heating mechanism, and a base portion 14c.

The electrostatic chuck 14a includes, for example, a dielectric film and an electrode provided as an inner layer of the dielectric film. The electrostatic chuck 14a is provided on the base portion 14c. A DC power source (not shown) is connected to the electrode of the electrostatic chuck 14a. The wafer W placed on the electrostatic chuck 14a is attracted and held by the electrostatic chuck 14a by the electrostatic attraction force generated by applying a DC voltage from the DC power source to the electrode.

The heater 14b is configured to heat the wafer W supported by the stage 14. The heater 14b heats the wafer W supported by the stage (specifically, the electrostatic chuck 14a) by heating the stage 14 (specifically, the electrostatic chuck 14a). For example, a resistance heating type heater may be used as the heater 14b. In addition, the heater 14b is provided on, for example, the electrostatic chuck 14a.

The base portion 14c is formed in a disk shape using, for example, aluminum. Depending on the type of the heater 14b and the like, the heater 14b may be provided on the base portion 14c.

The stage 14 may be provided with a cooling mechanism for cooling the wafer W placed on the stage 14.

Further, the stage 14 is connected to a rotation/movement mechanism 15. The rotation/movement mechanism 15 includes, for example, a support shaft 15a and a drive part 15b. The support shaft 15a, extends in the vertical direction so as to penetrate the bottom wall of the processing container 10. A sealing member SL1 is provided between the support shaft 15a and the bottom wall of the processing container 10. The sealing member SL1 is a member that seals the space between the bottom wall of the processing container 10 and the support shaft 15a so that the support shaft 15a can rotate and move up and down. For example, the sealing member SL1 is a magnetic fluid seal. The upper end of the support shaft 15a is connected to the center of the lower surface of the stage 14, and the lower end thereof is connected to the drive part 15b. The drive part 15b includes a drive source such as a motor or the like and generates a drive force for rotating and moving the support shaft 15a up and down. As the support shaft 15a rotates about the axis AX1, the stage 14 is rotated about the axis AX1. As the support shaft 15a moves up and down, the stage 14 is moved up and down.

Above the stage 14, a holder 20amade of a conductive material is provided to hold a metallic material target 20. The holder 20a holds the target 20 so that the target 20 is located in the processing container 10. The holder 20a is attached to the ceiling of the processing container 10. A through-hole is formed at the attachment position of the holder 20a in the processing container 10. Further, an insulating member 10a is provided on the inner wall surface of the processing container 10 so as to surround the through-hole. The holder 20a is attached to the processing container 10 via the insulating member 10a so as to close the through-hole.

The holder 20a holds the target 20 on the front surface thereof so that the target 20 faces the stage 14. The target 20 is made of a metal which is a constituent element of a metal oxide film to be formed. The target 20 of this example is made of titanium (Ti), which is a constituent element of a TiO² film. Further, a power source 21 is connected to the holder 20a, and a negative DC voltage is applied from the power source 21 to the holder 20a. An AC voltage may be applied instead of the negative DC voltage.

Further, a magnet unit 22 is provided at a position on the back surface side of the holder 20a and outside the processing container 10. The magnet unit 22 forms a magnetic field that leaks to the front side of the tamet 20 held by the holder 20a.

The magnet unit 22 is connected to the movement mechanism 23. The movement mechanism 23 swings the magnet unit 22 along the back surface of the holder 20a in the apparatus depth direction (the Y direction in FIG. 2) and includes, for example, a rail 23a extending along the apparatus depth direction (the Y direction in FIG. 2) and a drive part 23b including a motor or the like. Due to the drive force generated by the drive part 23b, the magnet unit 22 is moved along the rail 23a in the apparatus depth direction (the Y direction in FIG. 2). More specifically, due to the drive force generated by the drive part 23b, the magnet unit 22 is moved to reciprocate between one end of the target 20 in the apparatus depth direction (the negative side end of the target 20 in the Y direction in FIG. 2) and the other end (the positive side end of the target 20 in the Y direction in FIG. 2) thereof. The drive part 23b is controlled by a controller U described later. By swinging the magnet unit 22 by the movement mechanism 23, it becomes possible to utilize substantially the entire target 20.

Further, the film forming apparatus 1 includes a shield part 30 that forms a processing space K2 in the processing container 10. The shield part 30 is provided in the processing container 10.

The shield part 30 includes a first shield member 31 and a second shield member 32. The first shield member 31 and the second shield member 32 are formed of, for example, aluminum.

The first shield member 31 is a pot-shaped member having an open upper portion. The first shield member 31 has a hole 31a formed on the bottom surface thereof to expose the processing space K2 to the wafer W placed on the stage 14. The first shield member 31 is supported in the processing container 10 via, for example, a support member (not shown).

The second shield member 32 is a lid member that closes the upper opening of the first shield member 31 and is formed so that the central portion in a plan view protrudes upward. The second shield member 32 has an opening 32a. Sputtered particles from the target 20 held by the holder 20a are supplied to the processing space K2 through the opening 32a.

Further, the second shield member 32 is configured to be rotatable about a central axis passing through the center in a top view. By rotating the second shield member 32, the opening 32a of the second shield member 32 can be caused to face the target 20 held by the holder 20a, or the portion of the second shield met ber 32 where the opening 32a is not formed can be caused to face the target 20.

Further, the film forming apparatus 1 includes a gas supply part 40 configured to supply a gas into the processing container 10. The gas supply part 40 supplies an inert gas such as an argon (Ar) gas or a krypton (Kr) gas, which is a sputtering gas, into the processing container 10. Further, the gas supply part 40 supplies an oxygen (O₂) gas into the processing container 10.

The gas supply part 40 includes, for example, gas sources 41 and 42, flow rate controllers 43 and 44 such as mass flow controllers or the like, and a gas introduction part 45. The gas source 41 stores the above-mentioned inert gas such as an Ar gas or the like. The gas source 42 stores an O₂ gas. The gas sources 41 and 42 are connected to the gas introduction part 45 via the flow rate controllers 43 and 44, respectively. The gas introduction part 45 is a member that introduces the gases from the gas sources 41 and 42 into the processing container 10.

As shown in FIG. 2, the film forming apparatus 1 further includes a controller U. The controller U is composed of, for example, a computer equipped with a CPU, a memory, and the like, and includes a program storage part (not shown). The program storage part stores programs for controlling the heater 14b, the power source 21, the gas supply part 40, and the like to realize the below-described film forming process in the film forming apparatus 1. The above programs may be recorded on a computer-readable storage medium and may be installed on the controller U from the storage medium. The storage medium may be transitory or non-transitory. In addition, a part or all of the programs may be realized by dedicated hardware (circuit board).

<Film Forming Process>

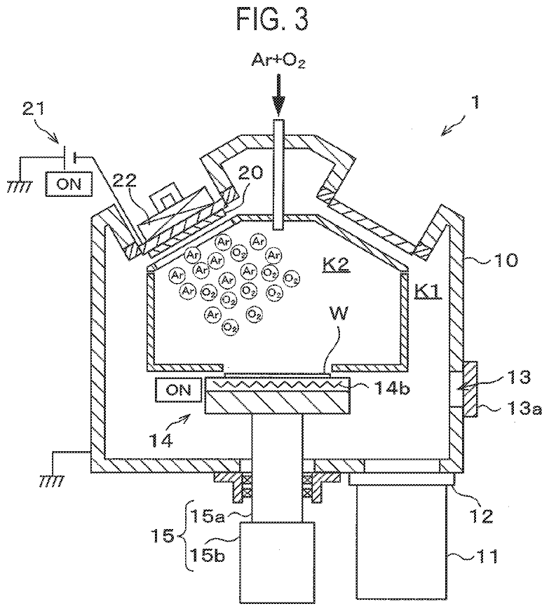

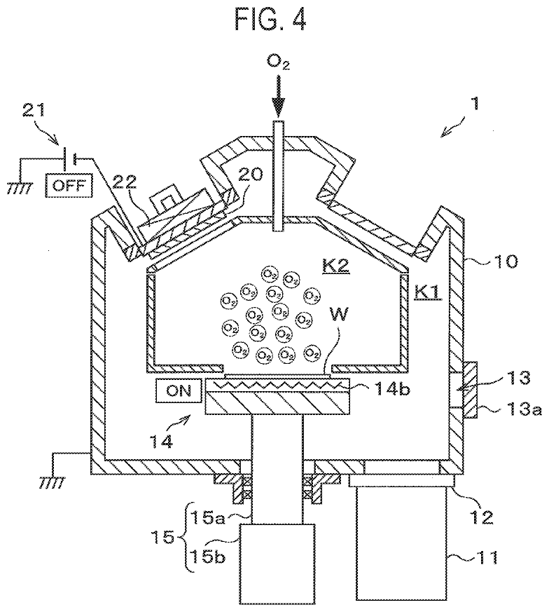

Next, an example of the film forming process using the film forming apparatus 1 will be described with reference to FIGS. 3 and 4. FIGS. 3 and 4 are diagrams showing the state of the inside of the processing container 10 during the film forming process. The following process is performed under the control of the controller U.

(S1:Loading)

First, the wafer W is loaded into the processing container 10.

Specifically, the gate valve 13a is opened, and the transfer mechanism (not shown) holding the wafer W is inserted into the processing container 10 from the vacuum atmosphere transfer chamber (not shown) adjacent to the processing container 10 adjusted to a desired pressure by the exhaust device 11 via the loading/unloading port 13. Then, the wafer W is transferred to above the stage 14 heated to a predetermined temperature by the heater 14b. Next, the wafer W is delivered onto the raised support pins (not shown), Thereafter, the transfer mechanism is withdrawn from the processing container 10, and the gate valve 13a is closed. At the same time, the support pins are lowered. The wafer W is placed on the stage 14 and is attracted and held by the electrostatic attraction force of the electrostatic chuck 14a. Further, the stage 14 is raised, and the wafer W is moved to a position directly under the hole 31a of the shield part 30.

(S2:Formation of Predetermined Film)

Next, a predetermined film is formed on the wafer W by reactive sputtering in a metal mode in the processing container 10. Specifically, the predetermined film is a metal oxide film, i.e., a, titanium monoxide (TiO) film, which contains a metal (specifically, Ti) in a higher proportion than a TIO₂ film which is a target titanium oxide film to be formed.

In this step, for example, as shown in FIG. 3, an Ar gas and an O₂ gas, which are sputtering gases, are supplied from the gas supply part 40 (see FIG. 2) into the processing space K2 of the processing container 10. The flow rate of the Ar gas is, for example, 20 sccm to 80 sccm. The flow rate of the O₂ gas is a flow rate at which reactive sputtering is performed in a metal mode and which is determined based on the result of a test or the like performed in advance. The flow rate of the O₂ gas is, for example, 1 sccm to 40 sccm. When the range of the flow rate (i.e., partial pressure) of the Ar gas is set higher (or wider) than the above range, the range of the flow rate (i.e., partial pressure) of the O₂ gas is set higher (or wider) than the above range. In this step, electric power is supplied from the power source 21 to the target 20 together with the supply of the Ar gas and the O₂ gas. Further, the magnet unit 22 is moved by the movement mechanism 23 so as to repeatedly reciprocate, i.e., swing, above the target 20 along the apparatus depth direction (Y direction in FIG. 2). The Ar gas in the processing container 10 is ionized by the electric power supplied from the power source 21. The electrons generated by the ionization are drifted by the magnetic field (i.e., the leaked magnetic field) formed in front of the target 20 by the magnet unit 22, and plasma having a high density is generated. The surface of the target 20 is sputtered by the Ar ions generated in this plasma to emit sputtered Ti particles. The sputtered Ti particles emitted from the target 20 react with the O₂ gas, whereby a titanium oxide film is formed on the surface of the water W on the stage 14 heated to a predetermined temperature by the heater 14b. At this time, the flow rate of the O₂ gas is a flow rate at which the film is formed by the reactive sputtering in the metal mode as described above. Therefore, the titanium oxide produced by the reaction between the sputtered Ti particles and the O₂ gas is TiO having a higher proportion of Ti metal than TiO₂ which is a target titanium oxide. A TiO film is formed on the wafer W.

This step is performed for, for example, 2 seconds to 10 seconds, and a TiO film having an atomic-level thickness, specifically, a TiO film having a thickness of 1 to 4×10⁻¹⁰ m is formed on the wafer W. Further, the temperature of the stage 14 in this step is 80 degrees C. or higher.

in the subject specification, the reaction mode and the metal mode are the following modes. The reaction mode is a mode in which a target metal oxide film close to stoichiometry is formed when forming a metal oxide film on the wafer W by reactive sputtering and is a mode in which the deposition rate is slowed down due to the adhesion of atoms of an O₂ gas to the surface of the target 20. On the other hand, the metal mode is a mode in which a film having a large proportion of metal contained in the film is formed when forming a metal oxide film on the wafer W by reactive sputtering and is a mode in which the target metal is exposed without the O₂ gas atoms adhering to the surface of the target 20 and the deposition rate is high.

(S3:Target Titanium Oxide Film Formation)

Subsequent to step S2, the predetermined film reacts with the O₂ gas in the processing container 10 to form a target titanium oxide film to be formed. The target titanium oxide film is the above-described TIO₂ film, more specifically, a TiO₂ film having an anatase-type crystal structure.

In this step, for example, the supply of the Ar gas from the gas supply part 40 into the processing space 12 of the processing container 10, the power supply from the power source 21 to the target 20, and the swing of the magnet unit 22 are stopped. As shown in FIG. 4, the supply of the O₂ gas from the gas supply part 40 into the processing space K2 of the processing container 10 and the heating of the stage 14 by the heater 14b are continued. For example, the flow rate of the O₂ gas and the temperature of the stage 14 are common in steps S2 and S3. The TiO film formed on the wafer W on the stage 14 is in a state of being activated by the heat from the heated stage 14, Therefore, when the TiO film is exposed to the O₂ gas in the processing space K2, it reacts with the O₂ gas and becomes a TiO₂ film.

This step is performed, for example, for 5 to 10 seconds.

The above-described steps S2 and S3 are alternately repeated until a TiO₂ film having a desired thickness is formed on the wafer W. For example, the above-described steps S2 and S3 are repeated 350 to 750 cycles (times) so that a film having a thickness of about 100 nm is formed in a total time of 5000 to 10000 seconds. In steps S2 and S3, the stage 14 on which the wafer W is placed may be rotated. Further, in step S3, subsequent to step S2, the opening of the second shield member 32 may be Left facing the target 20 held by the holder 20a.

(Unloading)

Thereafter, the wafer W is unloaded from the processing container 10. Specifically, the wafer W is unloaded from the processing container 10 in an operation opposite to the loading operation. Then, the process returns to the above-mentioned loading step, and the next wafer W to he film-formed is processed in the same manner.

<Main Effects of the Present Embodiment>

As described above, in the film forming method according to the present embodiment, (a) forming a predetermined film on a wafer W by reactive sputtering. in a metal mode, and (b) forming a target titanium oxide film, i.e., a TiO₂ film by causing the predetermined film to react with an O₂ gas are alternately repeated. As a result, a TiO₂ film having a desired thickness is formed. The predetermined film formed on the wafer W in the metal mode in (a) is a film (e.g., a TiO film) having a larger proportion of metal than the TiO₂ film formed in the reaction mode and has a low refractive index. However, the deposition rate in the metal mode in (a) is 20 times or more higher than the deposition rate in the reaction mode (see FIG. 1). Then, the TiO film formed in (a) is converted into the TiO₂ film in subsequently-performed (b). Further, the time required for (b) is about the same as the time required for (a). Therefore, when the TiO₂ film is formed in (a) and (b), the time required to form the TiO₂ film having the same thickness is shorter than that in the case of forming the TiO₂ film in the reaction mode. Accordingly, by repeating (a) and (b), a TiO₂ film having a desired thickness and a high refractive index can be formed at a high deposition rate.

In addition, unlike the present embodiment, in a method of forming a TiO₂ film having a target thickness by forming a Ti film having a thickness equivalent to the final target thickness of the TiO₂ film at one time and oxidizing the Ti film in an oxidizing furnace, it is necessary to keep the oxidizing furnace at 500 degrees C. or higher. In the method according to the present embodiment, the TiO₂ film can be formed by a low-temperature process such as 250 degrees C. or the like as compared with the above-mentioned method using the oxidizing furnace.

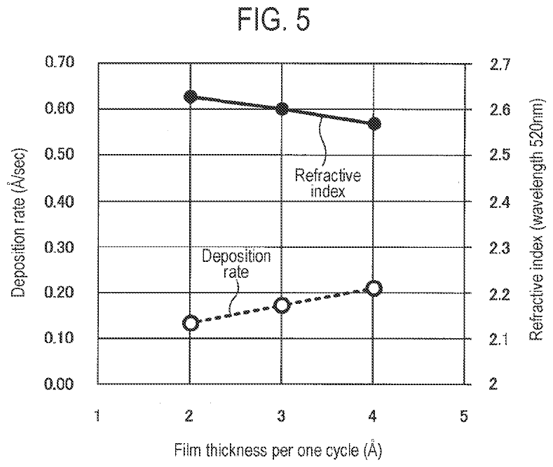

FIG. 5 is a diagram showing the refractive index (for the light having a wavelength of 520 nm) of the TiO₂ film actually formed by the film forming method according to the above-described embodiment and the deposition rate at that time. The main conditions when forming the TiO₂ film are as follows.
Electric power supplied to target 20 in (a): DC power 500 W
Inert gas supplied in (a): Ar gas
Temperature of stage 14: 250 degrees C.
Flow rate of Ar gas in (a): 30 sccm
Flow rate of O₂ gas: 20 sccm
TiO film thickness per one cycle: 2 to 4 Å
Time of (b): 5 to 10 seconds
Number of cycles (number of repetitions): 350
Final thickness of TiO₂ film: 100 nm

As is clear from FIG. 5, the refractive index of the TiO₂ film formed by the film forming method according to the present embodiment is as high as 2.5 or more and is about the same as the TiO₂ film formed by the reactive sputtering in the reaction mode shown in FIG. 1. Further, as shown in FIG. 1, the deposition rate of the TiO₂ film having a refractive index of about 2.6 formed by the reactive sputtering in the reaction mode is about 0.02 Å/s. On the other hand, the deposition rate of the TiO₂ film formed by the film forming method according to the present embodiment is about 0.12 Å/s to 0.2 Å/s, which is 5 to 10 times faster than the deposition rate obtained by the reactive sputtering in the reaction mode.

Further, according to the tests conducted by the present inventors, the extinction coefficient of the TiO₂ film formed by the film forming method according to the present embodiment under the above conditions is as low as 0.00 or less. That is, according to the present embodiment, the TiO₂ film having an anatase-type crystal structure that satisfies the optical characteristics of a transparent film, i.e., a high refractive index and a low extinction coefficient, can be formed on the wafer W at a deposition rate that ensures productivity.

According to the present disclosure in some embodiments, it is possible to form a desired metal oxide film at a high deposition rate.

The embodiments disclosed herein should be considered to be exemplary and not limitative in all respects. The above-described embodiments may be omitted, replaced, or modified in various forms without departing from the scope of the appended claims and their gist.

What is claimed is:

1. A film forming apparatus for forming a metal oxide film on a substrate, comprising:
a substrate support part configured to support the substrate;
a heating mechanism configured to heat the substrate supported by the substrate support part;
a processing container in which the substrate support part is provided;
a holder configured to hold a metal material target inside the processing container and connected to a power source;
a gas supply part configured to supply an oxygen gas into the processing container; and
a controller,
wherein the controller is configured to control the heating mechanism, the power source, and the gas supply part so as to execute alternately and repeatedly:
forming a predetermined film on the substrate inside the processing container by reactive sputtering in a metal mode; and
forming a target metal oxide film by causing the predetermined film to react with an oxygen gas inside the processing container.

2. The film forming apparatus of claim 1, wherein in the forming the predetermined film, electric power is supplied from the power source to the holder and the substrate supported by the substrate support part is heated by the heating mechanism, and
in the forming the target metal oxide film, the substrate supported by the substrate support part is heated without supplying the electric power from the power source to the holder.

3. The film forming apparatus of claim 2, wherein the predetermined film has a thickness of 2 to 4 Å and is formed by executing the forming the predetermined film once.

4. film forming apparatus of claim 3, wherein the predetermined film is a metal oxide film containing a metal in a higher proportion than the target metal oxide film.

5. The film forming apparatus of claim 4, wherein the target metal oxide film is a titanium dioxide film, a silicon dioxide film, or an oxide film containing both titanium and silicon.

6. film forming apparatus of claim 5, wherein the target metal oxide film is a titanium dioxide film having an anatase-type crystal structure.

7. The film forming apparatus of claim 1, wherein the predetermined film has a thickness of 2 to 4 Å and is formed by executing the forming the predetermined film once.

8. The film forming apparatus of claim 1, wherein the predetermined film is a metal oxide film containing a metal in a higher proportion than the target metal oxide film.

9. The film forming apparatus of claim 1, wherein the target metal oxide film is a titanium dioxide film, a silicon dioxide film, or an oxide film containing both titanium and silicon.

10. A film forming method of forming a metal oxide film on a substrate, the film forming method comprising:
forming a predetermined film on the substrate by reactive sputtering in a metal mode; and
forming a target metal oxide film by causing the predetermined film to react with an oxygen gas,
wherein the forming the predetermined film and the forming the target metal oxide film are executed alternately and repeatedly.

11. The film forming method of claim 10, Wherein in the forming the predetermined film, the substrate is heated while supplying electric power to a holder configured to hold a target, and
in the forming the target metal oxide film, the substrate is heated without supplying the electric power to the holder.

12. The film forming method of claim 11, wherein the predetermined film has a thickness of 1 to 4×10⁻¹⁰ m and is formed by executing the forming the predetermined film once.

13. The film forming method of claim 12, wherein the predetermined film is a metal oxide film containing a metal in a higher proportion than the target metal oxide film.

14. The film forming method of claim 13, wherein the target metal oxide film is a titanium dioxide film, a silicon dioxide film, or an oxide film containing both titanium and silicon.

15. The film forming method of claim 14, wherein the target metal oxide film is a titanium dioxide film having an anatase-type crystal structure.

16. The film forming method of claim 10, wherein the predetermined film has a thickness of 1 to 4×10⁻¹⁰ m and is formed by executing the forming the predetermined film once.

17. The film forming method of claim 10, wherein the predetermined film is a metal oxide film containing a metal in a higher proportion than the target metal oxide film.

18. The film forming method of claim 10, wherein the target metal oxide film is a titanium dioxide film, a silicon dioxide film, or an oxide film containing both titanium and silicon.
